(19) United States
(12) Patent Application Publication
(10) Pub. No.: US 2021/0260680 A1
(43) Pub. Date: Aug. 26, 2021

(54) LIQUID AGENT SUPPLY DEVICE AND LIQUID AGENT SUPPLY METHOD

(71) Applicant: Panasonic Intellectual Property Management Co., Ltd., Osaka (JP)

(72) Inventors: Hiroto MIYAZAKI, Fukuoka (JP); Kazuki FUKADA, Osaka (JP); Kazunori ISHIKAWA, Osaka (JP); Wanyu TIE, Osaka (JP)

(21) Appl. No.: 17/252,020

(22) PCT Filed: Jul. 9, 2019
(86) PCT No.: PCT/JP2019/027088

§ 371 Date: Dec. 14, 2020

(30) Foreign Application Priority Data
Sep. 3, 2018 (JP) 2018-164689

(51) Int. Cl. B23K 3/06; H05K 3/34; B23K 3/08

(52) U.S. Cl. CPC B23K 3/0607; B23K 3/08; H05K 3/34

(57) ABSTRACT

A liquid agent supply device includes: a holder that holds a board; a supply head including a plurality of nozzles for supplying a liquid agent to a plurality of supply positions on the board held by the holder are arranged; and a supply head mover that relatively moves the board and the supply head, wherein the supply head mover relatively moves the board and the supply head according to a first movement method in which the board and the supply head relatively move along a specific direction determined regardless of supply positions among the plurality of supply positions, in a supply range including the plurality of supply positions.

### TECHNICAL FIELD

This disclosure relates to a liquid agent supply device and a liquid agent supply method.

### BACKGROUND ART

A technique for applying solder to an application target position while sequentially moving the nozzle of the dispenser to the application target position on the board based on the application position information indicating the solder application target position on the board is disclosed (for example, Patent Literature 1 (PTL 1)). With this, the solder can be applied to the application target position on the board with high accuracy.

### CITATION LIST

### Patent Literature

PTL 1: Japanese Unexamined Patent Application Publication No. 2009-164450

### SUMMARY OF THE INVENTION

### Technical Problems

As a method of applying solder onto the board, there is a method performed by screen printing in addition to a method performed by a dispenser, which is the method disclosed in PTL 1 described above. However, since the application range has become reduced diametrically due to the miniaturization of mounted parts and the like in recent years, there is a problem in screen printing that it is difficult to form a screen mask corresponding to the diametrically reduced application range. In addition, since flexible boards and the like that are soft and difficult to fix are often used in recent years, there is a problem in screen printing that printing misalignment occurs during printing with a squeegee. On the other hand, when a dispenser is used, it is possible to apply solder pinpointedly to a diametrically reduced application range with a nozzle, and since a squeegee or the like is not used, the problem of printing misalignment is unlikely to occur.

However, the number of application target positions on the board may be several thousand points or the like, and rapid acceleration/deceleration is repeated when the nozzle of the dispenser moves to each application target position in order to shorten the time required for the application. In order to realize such rapid acceleration/deceleration, a powerful drive source and a highly rigid housing that converges the vibration accompanying the rapid acceleration/deceleration are used, and the cost and size of the device have been increased.

Therefore, an object of the present disclosure is to provide a liquid agent supply device or the like capable of reducing the cost and size of the device.

### Solutions to Problems

A liquid agent supply device according to one aspect of the present disclosure includes: a holder that holds a board; a supply head including a plurality of nozzles for supplying a liquid agent to a plurality of supply positions on the board held by the holder are arranged; and a relative mover that relatively moves the board and the supply head, wherein the relative mover relatively moves the board and the supply head according to a first movement method in which the board and the supply head relatively move along a specific direction determined regardless of supply positions among the plurality of supply positions, in a supply range including the plurality of supply positions.

It should be noted that these comprehensive or specific aspects may be realized by a system, device, method, recording medium, or computer program, and may be realized by any combination of the system, device, method, recording medium, and computer program.

### Advantageous Effects of Invention

According to the liquid agent supply device and the like according to the present disclosure, it is possible to reduce the cost and size of the device.

### BRIEF DESCRIPTION OF DRAWINGS

FIG. 1 is a top view of the liquid agent supply device according to Embodiment 1.

FIG. 2 is a side view of the liquid agent supply device according to Embodiment 1.

FIG. 3 is an external perspective view of the periphery of the supply head according to Embodiment 1.

FIG. 4 is a configuration diagram of a computer according to Embodiment 1.

FIG. 5 is a side perspective view of the supply head according to Embodiment 1.

FIG. 6 is a diagram for explaining a mechanism for discharging the liquid agent of the supply head according to Embodiment 1.

FIG. 7 is a flowchart showing an example of the operation of the liquid agent supply device according to Embodiment 1.

FIG. 8 is a diagram for explaining an example of the first movement method.

FIG. 9 is a diagram for explaining another example of the first movement method.

FIG. 10 is a diagram for explaining an example of the second movement method.

FIG. 11 is an external perspective view of the periphery of the supply head according to Embodiment 2.

FIG. 12 is a flowchart showing an example of the operation of the liquid agent supply device according to Embodiment 2.

### DESCRIPTION OF EXEMPLARY EMBODIMENTS

A liquid agent supply device of the present disclosure includes: a holder that holds a board; a supply head including a plurality of nozzles for supplying a liquid agent to a plurality of supply positions on the board held by the holder are arranged; and a relative mover that relatively moves the board and the supply head, wherein the relative mover relatively moves the board and the supply head according to a first movement method in which the board and the supply head relatively move along a specific direction determined regardless of supply positions among the plurality of supply positions, in a supply range including the plurality of supply positions.

For example, the first movement method is a method in which the supply head moves in a direction substantially orthogonal to the arrangement direction of a plurality of nozzles arranged on a straight line as a specific direction. A plurality of nozzles are arranged in the supply head, and the liquid agent can be supplied to a plurality of supply positions by the plurality of nozzles while the board and the supply head move relatively in a specific direction according to the first movement method. That is, since the liquid agent can be supplied to many supply positions at once by one relative movement in a specific direction between the board and the supply head including the plurality of nozzles are arranged, the time required to supply the liquid agent to a plurality of supply positions can be shortened. In addition, since the time can be shortened by supplying the liquid agent to many supply positions at once, it is not always necessary to move the board and the supply head at a relatively high speed in order to shorten the time. Therefore, by moving the board and the supply head at a relatively low speed, it is not necessary to prepare a powerful drive source for realizing rapid acceleration/deceleration and a highly rigid housing that converges vibrations associated with rapid acceleration/deceleration so that it is possible to reduce the cost and size of the device.

In addition, when the plurality of nozzles move according to the first movement method, the supply head may supply the liquid agent to the supply positions without relatively stopping at the supply positions.

In this way, since it is not necessary to stop the supply head relatively at the supply positions, it turns out that it is not necessary for a powerful drive source for realizing rapid acceleration/deceleration and a highly rigid housing that converges vibrations associated with rapid acceleration/deceleration to be prepared.

In addition, the board and the supply head may reciprocate relatively along the specific direction in the first movement method.

According to this, it is possible to flexibly supply the liquid agent to a plurality of supply positions on the board.

For example, a route in which the board and the supply head reciprocate relatively may include an outward route and a return route with an interval therebetween.

According to this, the board and the supply head relatively reciprocate along a specific direction at regular intervals between the outward route and the return route so that the supply head moves relatively from one end to the other end of the board. Therefore, for example, even when the length from the one end to the other end of the board is larger than the length of the supply head including a plurality of nozzles are arranged, and the liquid agent cannot be supplied to all of the plurality of supply positions on the board by one movement in a specific direction, the relative reciprocating movement between the board and the supply head allows the liquid to be supplied to all of the plurality of supply positions.

In addition, the interval may be narrower than the interval at which the plurality of nozzles are arranged.

According to this, the liquid agent can be accurately supplied to the supply positions.

In addition, a route in which the board and the supply head reciprocate relatively may include an outward route and a return route that are the same route.

According to this, even if a sufficient amount of liquid agent cannot be supplied to the supply positions by one relative movement between the board and the supply head in a specific direction, it is possible to supply a sufficient amount of the liquid agent to the supply positions because the relative reciprocation between the board and the supply head is performed in the same route and the liquid agent is supplied to the same supply positions on each of the outward route and the return route.

In addition, the liquid agent supply device further includes: a selector that selects a relative movement method between the board and the supply head from a plurality of movement methods including the first movement method; and a calculator that calculates, for each of the plurality of movement methods, a supply time required for supplying the liquid agent to the plurality of supply positions, wherein the selector may select a relative movement method between the board and the supply head from the plurality of movement methods based on a calculation result of the supply time. Specifically, the relative mover relatively moves the board and the supply head according to a second movement method in which the board and the supply head move relative to each other based on a positional relationship between the plurality of supply positions, and the selector may select one of the first movement method or the second movement method from the plurality of movement methods.

According to this, an optimum supply time can be obtained by selecting the optimum movement method from a plurality of movement methods (specifically, the first movement method and the second movement method).

In addition, the relative mover may relatively move the board and the supply head by combining the first movement method and the second movement method.

According to this, a more optimum supply time can be obtained by combining the first movement method and the second movement method.

In addition, the liquid agent supply device may further include a recognizer that recognizes a mark attached to the board.

According to this, for example, it can be recognized that the board has been transported to a specific position (for example, a position for supplying the liquid agent to the supply positions on the board) by a transport device or the like used in a mass production process or the like.

In addition, the holder may have a clamping mechanism for clamping an end portion of the board.

According to this, when the liquid agent is supplied to the supply positions on the board, the board can be fixed by the clamp mechanism, and the liquid agent can be suppressed from being supplied to a position deviated from the desired supply positions.

In addition, the liquid agent may be solder.

According to this, the solder can be supplied to the supply positions on the board.

A method for supplying a liquid agent according to the present disclosure for a liquid agent supply device that includes: a holder that holds a board; a supply head including a plurality of nozzles for supplying the liquid agent to a plurality of supply positions on the board held by the holder are arranged; and a relative mover that relatively moves the board and the supply head, includes relatively moving the board and the supply head according to a first movement method in which the board and the supply head relatively move along a specific direction determined regardless of supply positions among the plurality of supply positions, in a supply range including the plurality of supply positions.

According to this, it is possible to provide a liquid agent supply method that enables cost reduction and miniaturization of the device.

It should be noted that each of the embodiments described below shows comprehensive or specific examples. The numerical values, shapes, components, arrangement positions and connection forms of the components, steps, order of steps, and the like shown in the following embodiments are examples, and are not intended to limit the present invention. In addition, among the components in the following embodiments, the components not described in the independent claims indicating the highest level concept are described as arbitrary components. In addition, each figure is a schematic view and is not necessarily exactly illustrated.

In addition, the X-axis, Y-axis, and Z-axis are used for explanation in the specification and drawings. The X-axis, Y-axis and Z-axis represent the three axes of the three-dimensional Cartesian coordinate system. In the embodiments, for example, the Z-axis direction is the vertical direction, and the direction perpendicular to the Z-axis (the direction parallel to the XY plane) is the horizontal direction. It should be noted that the positive direction of the Z axis is vertically upward.

### Embodiment 1

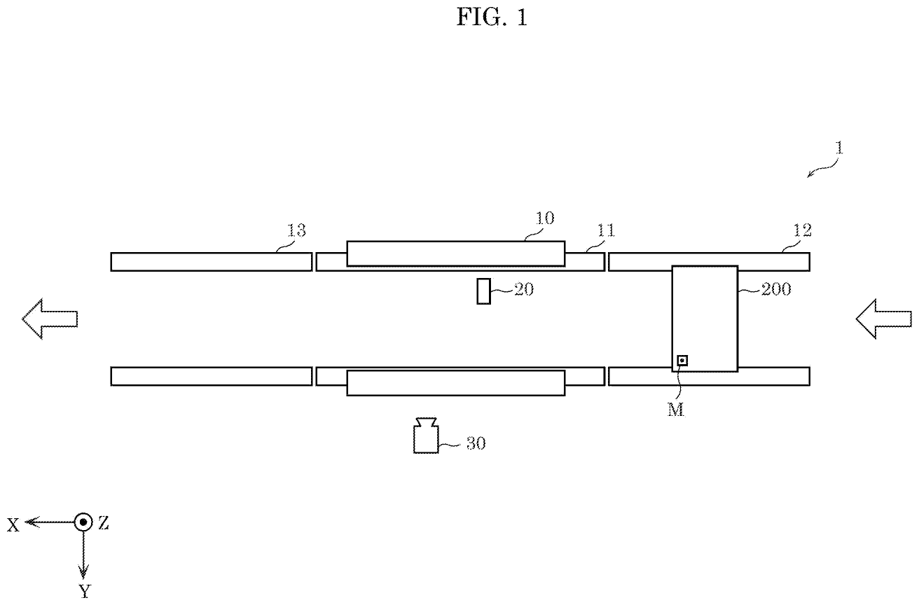

Hereinafter, Embodiment 1 will be described with reference to FIG. 1 to FIG. 10.

### [Overall Configuration of Liquid Agent Supply Device]

First, the overall configuration of liquid agent supply device 1 according to Embodiment 1 will be described with reference to FIG. 1 to FIG. 3.

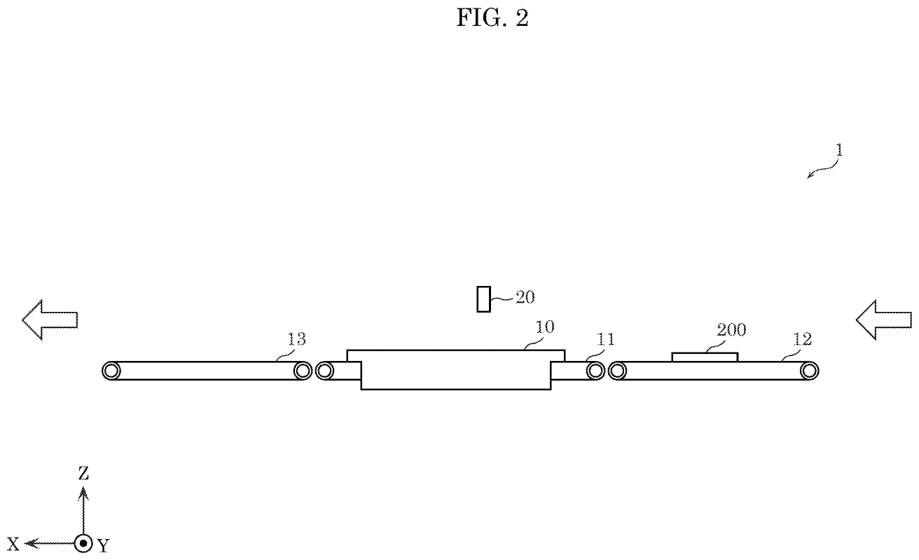

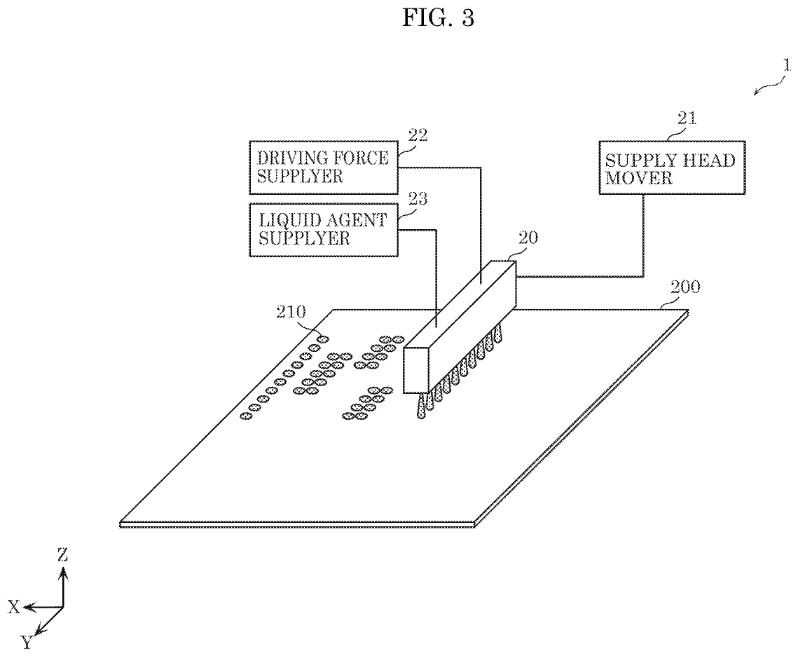

FIG. 1 is a top view (viewed from the plus side in the Z-axis direction) of liquid agent supply device 1 according to Embodiment 1. FIG. 2 is a side view (viewed from the plus side in the Y-axis direction) of liquid agent supply device 1 according to Embodiment 1. FIG. 3 is an external perspective view of the periphery of supply head 20 according to Embodiment 1.

Liquid agent supply device 1 is a device used in a mass production process or the like, and specifically, is a device for supplying a liquid agent for mounting a component on board 200.

Board 200 is a board on which components are mounted, and is, for example, a printed circuit board such as a rigid board or a flexible board. The material of the rigid board is paper phenol, glass epoxy, or the like, but is not particularly limited. The material of the flexible board is polyimide, polyester, or the like, but is not particularly limited. In addition, board 200 is not limited to a plate shape, and may have a shape such as a cube or a sphere.

The liquid agent is, for example, solder (specifically, liquid cream solder or the like). It should be noted that the liquid agent may be an adhesive or the like for adhering the components to board 200. In addition, the liquid agent may be a silver paste or the like that forms a conductor pattern or the like on board 200.

Liquid agent supply device 1 includes holder 10, transporter 11, loader 12, unloader 13, supply head 20, and recognizer 30. In addition, liquid agent supply device 1 includes a relative mover, driving force supplier 22, and liquid agent supplier 23 as a configuration for performing relative movement of board 200 and supply head 20 and discharge of the liquid agent. It should be noted that supply head mover 21 moves supply head 20 as a relative mover, so that board 200 and supply head 20 move relatively in Embodiment 1. In FIG. 1 to FIG. 3, the illustration of the specific configuration of supply head mover 21, driving force supplier 22, and liquid agent supplier 23 is omitted. Therefore, supply head 20 is illustrated to be floating.

Transporter 11, loader 12, and unloader 13 are arranged side by side in the order of, for example, loader 12, transporter 11, and unloader 13 in the X-axis direction. Each of transporter 11, loader 12, and unloader 13 includes, for example, a pair of conveyors. Loader 12 loads board 200 supplied from the outside to transporter 11, transporter 11 delivers board 200 to unloader 13 after the supply of the liquid agent to loaded board 200 is completed, and unloader 13 unloads received board 200 to the outside. In this way, board 200 is transported to the plus side in the X-axis direction in the drawing by loader 12, transporter 11, and unloader 13.

Holder 10 is provided at a location where transporter 11 is disposed. Holder 10 is a mechanism for holding board 200 loaded into transporter 11, and has, for example, a clamp mechanism for clamping an end portion of board 200. With this, when the liquid agent is supplied to liquid agent supply positions 210 on board 200, board 200 can be fixed by the clamp mechanism, and it is possible to suppress the liquid agent from being supplied to a position deviated from the desired supply positions. In addition, holder 10 may include a stage on which board 200 is placed, and the fact that board 200 is placed on holder 10 (stage) is also referred to as board 200 being held.

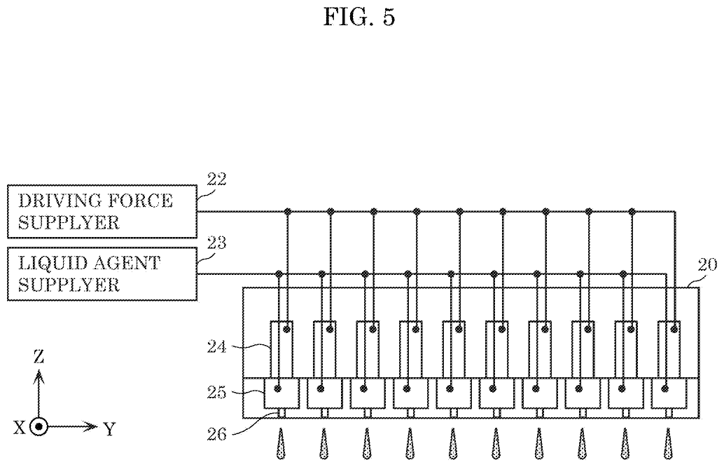

Supply head 20 is provided with a plurality of nozzles 26 (see FIG. 5 and the like described later) for supplying the liquid agent to the plurality of supply positions 210 on board 200 held by holder 10. FIG. 3 shows a plurality of supply positions 210 to which the liquid agent has been supplied. Supply head 20 can move in the X, Y, and Z axis directions above board 200 held by holder 10, and the liquid agent can be supplied to the plurality of supply positions 210 on board 200 during the movement.

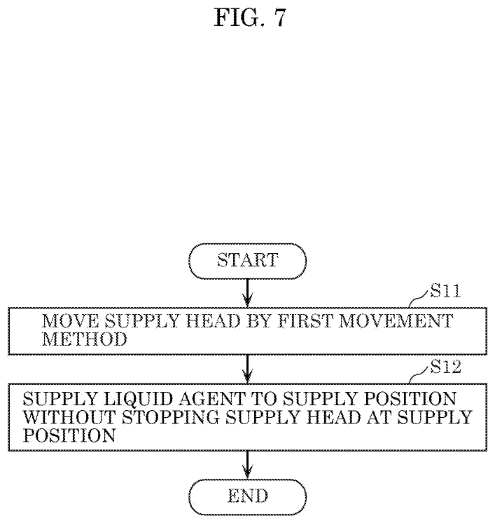

Supply head mover 21 moves supply head 20 in the X, Y, and Z axis directions. For example, supply head mover 21 is configured by a linear motor or the like to which supply head 20 is attached and by which supply head 20 can be moved in the X, Y, and Z axis directions. It should be noted that supply head mover 21 may be configured by a ball screw or the like. Supply head mover 21 relatively moves board 200 and supply head 20 according to a first movement method in which board 200 and supply head 20 relatively move along a predetermined direction determined regardless of supply positions 210 among the plurality of supply positions 210, in a supply range including the plurality of supply positions 210. Specifically, supply head mover 21 moves supply head 20 according to the first movement method. For example, in the present embodiment, the predetermined direction is determined in the X-axis direction regardless of supply positions 210. In addition, supply head mover 21 relatively moves board 200 and supply head 20 according to a second movement method in which board 200 and supply head 20 move relative to each other based on the positional relationship of each of the plurality of supply positions 210. Specifically, supply head mover 21 moves supply head 20 according to the second movement method. When supply head 20 moves according to the first movement method, the plurality of nozzles 26 do not stop relatively at supply positions 210 (specifically, supply head 20 itself does not stop at supply positions 210) to supply the liquid agent to supply positions 210. The first movement method and the second movement method will be described in detail with reference to FIG. 7 to FIG. 10 described later.

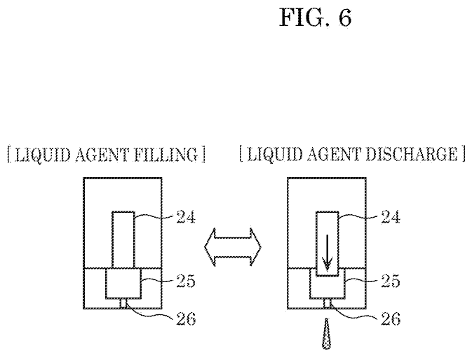

Driving force supplier 22 supplies the driving force for discharging the liquid agent from nozzle 26 to supply head 20. Liquid agent supplier 23 supplies (fills) the liquid agent to supply head 20. Driving force supplier 22 and liquid agent supplier 23 will be described in detail with reference to FIG. 5 and FIG. 6 described later.

Recognizer 30 is, for example, a camera and recognizes mark M (alignment mark) attached to board 200. With this, it is possible to recognize that the board has been transported to a specific position (for example, a position for supplying the liquid agent onto board 200), and holder 10 can hold board 200 at an accurate position.

### [Computer for Liquid Agent Supply Device]

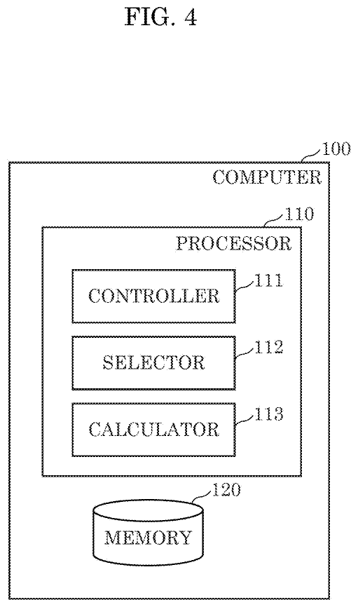

Control for the movement of supply head 20, the discharge of the liquid agent, and the like is performed by, for example, computer 100 included in liquid agent supply device 1. Computer 100 will be described with reference to FIG. 4. It should be noted that computer 100 may be provided separately from liquid agent supply device 1. For example, computer 100 may be a server device or the like.

FIG. 4 is a configuration diagram of computer 100 according to Embodiment 1.

Computer 100 is a computer including processor 110 (microprocessor), memory 120, a user interface (not shown), and the like. The user interface includes, for example, an input device such as a display, a keyboard, and a touch panel. Memory 120 is a ROM, RAM, or the like, and can store a control program (computer program) executed by processor 110. Controller 111, selector 112, and calculator 113, which are functional components included in processor 110, are realized by processor 110 operating according to the control program. It should be noted that computer 100 may have one memory or a plurality of memories, and here, one or a plurality of memories are indicated as memory 120.

Controller 111 controls the relative movement between board 200 and supply head 20 and the discharge of the liquid agent. Specifically, controller 111 controls supply head mover 21, driving force supplier 22, and liquid agent supplier 23. Supply head 20 can be moved by controller 111 controlling supply head mover 21. Specifically, supply head 20 can be moved by controller 111 controlling a linear motor or the like that generates a driving force for moving supply head 20. In addition, supply head 20 can supply the liquid agent to board 200 by controller 111 controlling driving force supplier 22 and liquid agent supplier 23.

Selector 112 selects a relative movement method between board 200 and supply head 20 from a plurality of movement methods including the first movement method. Specifically, selector 112 selects one of the first movement method or the second movement method from the plurality of movement methods. A program that makes board 200 and supply head 20 relatively movable according to a specific movement method, such as the first movement method and the second movement method, is stored in memory 120. Supply head mover 21 moves supply head 20 according to the selected movement method.

Calculator 113 calculates the supply time required for supplying the liquid agent to the plurality of supply positions 210 for each of the plurality of movement methods. For example, data relating to board 200 (specifically, Gerber data indicating the respective sizes of the plurality of supply positions 210, the respective coordinates of the plurality of supply positions 210 on board 200, the size of board 200, and the like) is stored in memory 120, and calculator 113 calculates the supply time based on the data. It should be noted that recognizer 30 may recognize the respective sizes of the plurality of supply positions 210, the respective coordinates of the plurality of supply positions 210 on board 200, the size of board 200, and the like, and calculator 113 may calculate the supply time based on the recognition result. It should be noted that the supply time may include not only the time for supply head 20 to move relatively on board 200 to supply the liquid agent to the plurality of supply positions 210, but also the time for the preparatory operation that needs to be performed for the supply of the liquid agent, and the like. In addition, the supply time may be the time required for supplying the liquid agent to all of the plurality of supply positions 210, or may be the time required for supplying the liquid agent to supply positions 210 included in each specific region (for example, a region where a plurality of supply positions 210 are densely packed, a region where supply positions 210 are discrete, or the like) on board 200.

### [Configuration of Supply Head and Mechanism of Discharging Liquid Agent]

Next, the specific configuration of supply head 20 and the mechanism of discharging the liquid agent by supply head 20 will be described with reference to FIG. 5 and FIG. 6.

FIG. 5 is a side perspective view of supply head 20 according to Embodiment 1.

A plurality of nozzles 26 are arranged on supply head 20. In addition, drive source 24 and liquid agent storage 25 are provided for each of the plurality of nozzles 26. Drive source 24, liquid agent storage 25, and nozzles 26 are not actually visible from the side surface of supply head 20 because they are provided inside supply head 20, for example, but since FIG. 5 is a side perspective view, these are illustrated.

The plurality of nozzles 26 are arranged linearly in the Y-axis direction at the lower end (minus side in the Z-axis direction) of supply head 20, and each of them discharges the liquid agent toward board 200. In FIG. 5, ten nozzles 26 are arranged on supply head 20, but in fact, for example, several thousand nozzles 26 are arranged. The diameter of the liquid agent discharge port of nozzle 26 is, for example, on a scale of several tens of micrometers. In this case, the diameter of the liquid agent at supply positions 210 on board 200 when the liquid agent discharged from nozzle 26 is supplied to board 200 is, for example, on a scale of about several hundred micrometers. In addition, the interval of the liquid agent applied from the plurality of nozzles 26 is also, for example, on a scale of several tens of micrometers. It should be noted that the plurality of nozzles 26 may be arranged in a plurality of rows.

By supplying the liquid agent from liquid agent supplier 23 to liquid agent storage 25, the liquid agent is stored in liquid agent storage 25. For example, liquid agent supplier 23 and liquid agent storage 25 are connected by a tube or the like through which the liquid agent flows.

Drive source 24 discharges the liquid agent stored in liquid agent storage 25 from nozzle 26 by the driving force supplied from driving force supplier 22. Drive source 24 is configured by, for example, a piezo element. The piezo element has such a property that its shape is finely deformed when a voltage is applied. When drive source 24 is configured by a piezo element, the drive force supplied from drive force supplier 22 is a voltage, and drive force supplier 22 and drive source 24 are connected by, for example, wiring or the like. Here, the mechanism of discharging the liquid agent by drive source 24 will be described with reference to FIG. 6.

FIG. 6 is a diagram for explaining a mechanism for discharging the liquid agent of supply head 20 according to Embodiment 1.

When drive source 24 is configured by a piezo element, the liquid agent is discharged from nozzle 26 by utilizing the above property of the piezo element. Specifically, by applying a voltage to the piezo element configuring drive source 24, as shown on the right side of FIG. 6, the liquid agent is discharged from nozzle 26 so that the shape of the piezo element is deformed toward liquid agent storage 25 to push the liquid agent out of liquid agent storage 25. Then, by stopping the application of the voltage, as shown on the left side of FIG. 6, the shape of the piezo element is restored, and at that time, liquid agent storage 25 is filled with the liquid agent by the liquid agent supplied from liquid agent supplier 23 to liquid agent storage 25.

It should be noted that drive source 24 may be configured by, for example, an air cylinder and a spring. The air cylinder has a property of converting the energy of compressed air into linear motion, and the spring has a property of deforming when a force is applied and returning to its original state when the force is removed. When drive source 24 is configured by an air cylinder and a spring, the drive force supplied from drive force supplier 22 is compressed air, and drive force supplier 22 and drive source 24 are connected by, for example, a tube or the like through which air flows.

When drive source 24 is configured by an air cylinder and a spring, the liquid agent is discharged from nozzle 26 by utilizing the above properties of the air cylinder and the spring. Specifically, by supplying compressed air to the air cylinder configuring drive source 24, as shown on the right side of FIG. 6, the liquid agent is discharged from nozzle 26 so that the piston in the air cylinder moves toward liquid agent storage 25 to push the liquid agent out of liquid agent storage 25. At that time, the spring is deformed (for example, stretched). Then, by stopping the application of the voltage to discharge the charged electric charge in the piezo element, as shown on the left side of FIG. 6, the piston in the air cylinder is returned to the original position by the restoring force of the spring, and at that time, liquid agent storage 25 is filled with the liquid agent by the liquid agent supplied from liquid agent supplier 23 to liquid agent storage 25.

It should be noted that liquid agent storage 25 may be filled with the liquid agent by supplying compressed air to the air cylinder, and the piston in the air cylinder may move toward liquid agent storage 25 by the restoring force of the spring. That is, the state in which the spring is not deformed (the state in which compressed air is not supplied to the air cylinder) may be the state on the right side of FIG. 6, and the state in which the spring is deformed (the state in which compressed air is supplied to the air cylinder) may be the state on the left side of FIG. 6.

### [Movement Method of Supply Head]

Next, as a relative movement method between board 200 and supply head 20, specifically, the movement method of supply head 20 will be described with reference to FIG. 7 to FIG. 10. First, the first movement method will be described with reference to FIG. 7 to FIG. 9.

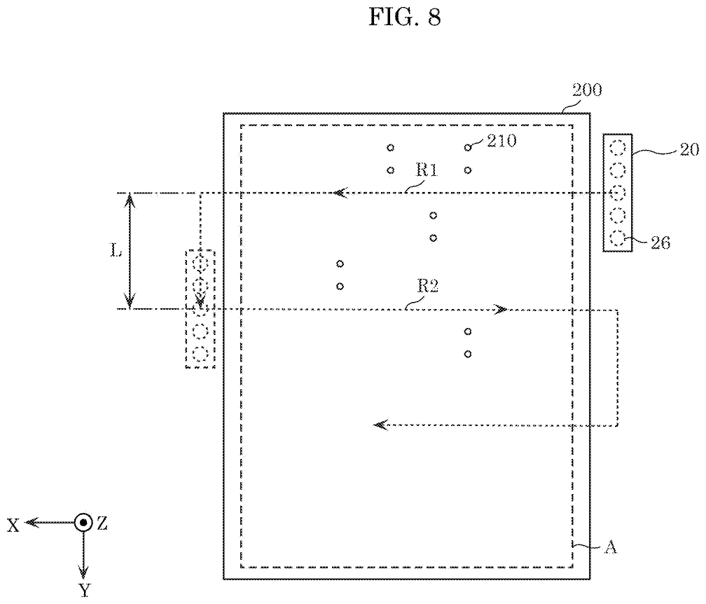

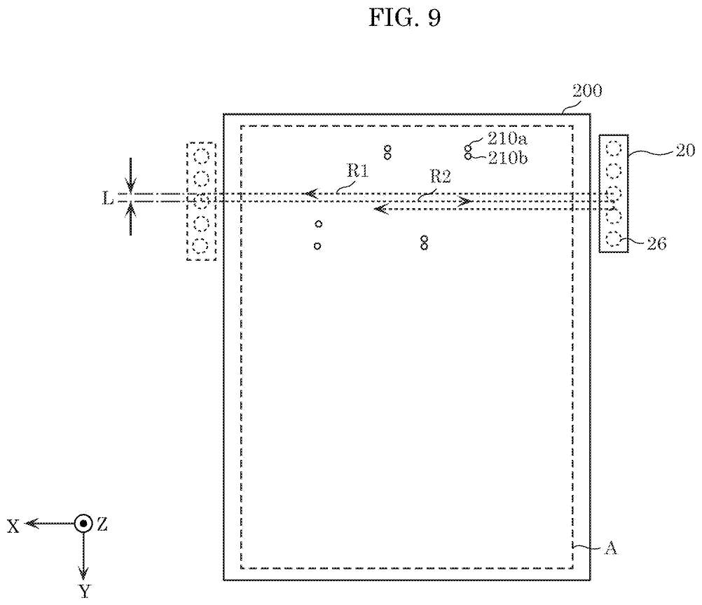

FIG. 7 is a flowchart showing an example of the operation of liquid agent supply device 1 according to Embodiment 1. FIG. 8 is a diagram for explaining an example of the first movement method. FIG. 9 is a diagram for explaining another example of the first movement method. FIG. 8 and FIG. 9 are top views (viewed from the plus side in the Z-axis direction) of board 200, and show the movement routes (routes R1, R2, and the like) of supply head 20. In addition, supply range A including a plurality of supply positions 210 is shown. In supply range A, the liquid agent is supplied to a plurality of supply positions 210 on board 200. In addition, five nozzles 26 are shown here as a plurality of nozzles 26.

As shown in FIG. 7, first, controller 111 moves supply head 20 to supply head mover 21 according to the first movement method in which supply head 20 moves along a specific direction determined regardless of supply positions 210 among a plurality of supply positions 210, in supply range A including the plurality of supply positions 210 (Step S11). Here, the specific direction is the X-axis direction, which is a direction substantially orthogonal to the arrangement direction (Y-axis direction) of the plurality of nozzles 26. For example, in the first movement method, supply head 20 moves on a straight line along the specific direction without changing the movement direction from the specific direction within supply range A.

A plurality of nozzles 26 are arranged in supply head 20, and the liquid agent can be supplied to the plurality of supply positions 210 by the plurality of nozzles 26 while supply head 20 moves in a specific direction according to the first movement method. As shown in FIG. 8, since the liquid agent can be supplied to many supply positions 210 (here, six supply positions 210) at once by one movement (for example, movement on route R1) of supply head 20 including the plurality of nozzles 26 are arranged in a specific direction, the time (supply time) required for supplying the liquid agent to the plurality of supply positions 210 can be shortened. In FIG. 8, five nozzles 26 are shown as the plurality of nozzles 26, but in fact, thousands of nozzles 26 are arranged in supply head 20. Therefore, the liquid agent can be actually supplied to thousands of supply positions 210 by one movement of supply head 20 in a specific direction. In addition, since the time reduction can be realized by supplying the liquid agent to many supply positions 210 at once, it is not always necessary to move supply head 20 at high speed in order to shorten the time. For example, for 10,000 supply positions 210, when the supply times were verified for each of the cases where the liquid agent is supplied to each of supply positions 210 by the movement at high speed using a supply head having one nozzle, and where the liquid agent is supplied to a plurality of supply positions 210 at once by the movement of supply head 20 at low speed, the latter was able to reduce the time by 10 times or more as compared with the former.

For example, when supply head 20 moves according to the first movement method, controller 111 causes a plurality of nozzles 26 to supply the liquid agent to supply positions 210 without stopping supply head 20 at supply positions 210 (Step S12). As described above, since it is not always necessary to move supply head 20 at high speed in order to shorten the time, by moving supply head 20 at low speed, the liquid agent can be supplied without stopping supply head 20 at supply positions 210, that is, without suddenly accelerating or decelerating supply head 20 in supply range A. Therefore, it is not necessary to prepare a powerful drive source for realizing rapid acceleration/deceleration and a highly rigid housing that converges the vibration caused by rapid acceleration/deceleration, and the cost and size of the device can be reduced. It should be noted that in the first movement method, supply head 20 may move at a constant speed in a specific direction in supply range A. With this, not only the rapid acceleration/deceleration of supply head 20 but also the simple acceleration/deceleration can be suppressed in supply range A, and the cost and size of the device can be further reduced.

In addition, board 200 and supply head 20 relatively reciprocate along a specific direction in the first movement method. Specifically, as shown in FIG. 8 and FIG. 9, supply head 20 reciprocates along a specific direction in the first movement method. With this, the liquid agent can be flexibly supplied to the plurality of supply positions 210 on board 200.

In addition, the route in which board 200 and supply head 20 relatively reciprocate includes an outward route and a return route with an interval therebetween. Specifically, the route in which supply head 20 reciprocates includes an outward route and a return route with an interval therebetween. Routes R1 and R2 shown in FIG. 8 and FIG. 9 are outward and return routes with interval L therebetween.

Interval L is determined so that, for example, the movement range on route R1 and the movement range on route R2 of supply head 20 do not overlap in the plan view of board 200, that is, when board 200 is viewed from the plus side in the Z-axis direction. Interval L shown in FIG. 8 is determined such that the movement range on route R1 and the movement range on route R2 of supply head 20 (specifically, the plurality of nozzles 26 groups) do not overlap in the plan view of board 200. With this, supply head 20 reciprocates along a specific direction with certain interval L between the outward route and the return route so that supply head 20 moves from one end to the other end (for example, from the minus side to the plus side in the Y-axis direction) of board 200. Therefore, for example, even when the length from the one end to the other end of board 200 is larger than the length of supply head 20 including the plurality of nozzles 26 are arranged as shown in FIG. 8, and the liquid agent cannot be supplied to all of the plurality of supply positions 210 on board 200 by one movement in a specific direction., the liquid agent can be supplied to all of the plurality of supply positions 210 by the reciprocating movement of supply head 20.

In addition, interval L may be narrower than the interval in which the plurality of nozzles 26 are arranged. For example, as in supply positions 210a and 210b shown in FIG. 9, the interval between supply positions 210 may be narrower than the interval in which the plurality of nozzles 26 are arranged. This is because in recent years, the use of parts having a size that is difficult to see with the naked eye, such as the so-called 0201 size, has been increasing, and the interval between supply positions 210 has become narrower corresponding to the mounting land of such parts. In such a case, if interval L is determined so that the movement range on route R1 and the movement range on route R2 of supply head 20 do not overlap in the plan view of board 200 as shown in FIG. 8, for example, the liquid agent may not be supplied to supply positions 210b. Therefore, interval L is made narrower than the interval in which the plurality of nozzles 26 are arranged as shown in FIG. 9. In other words, interval L is determined so that the movement range on route R1 and the movement range on route R2 of supply head 20 overlap in the plan view of board 200. With this, supply head 20 gradually moves from one end to the other end of board 200, and the liquid agent can be accurately supplied to supply positions 210. For example, interval L is determined to about ¼ of the interval in which the plurality of nozzles 26 are arranged.

In addition, although not shown, the route in which board 200 and supply head 20 reciprocate relatively (specifically, the route in which supply head 20 reciprocates) may include an outward route and a return route that are the same as each other. That is, when supply head 20 reciprocates, the route that has moved may be returned and the same route may be moved again. The larger the mounting land size of the component, the larger the amount of liquid agent required, so that it may not be possible to supply a sufficient amount of the liquid agent to supply positions 210 corresponding to the mounting land by one movement of supply head 20 in a specific direction depending on the size of the mounting land. In this case, the height of the liquid agent is not sufficient at supply positions 210, and there is a possibility that defects may occur in mounting parts or the like. On the other hand, the reciprocating movement of supply head 20 is performed in the same route, and the liquid agent is supplied to the same supply positions 210 in each of the outward route and the return route, so that a sufficient amount of the liquid agent can be supplied to supply positions 210.

It should be noted that the size of interval L when reciprocating, whether or not the reciprocating movement is performed on the same route, and the like are determined based on the data (specifically, Gerber data and the like) regarding board 200 stored in memory 120. That is, there may be such a case that the movement method of supply head 20 is different depending on a location of one board 200 such as a location where interval L becomes large or small, or a location where supply head 20 reciprocates on the same route.

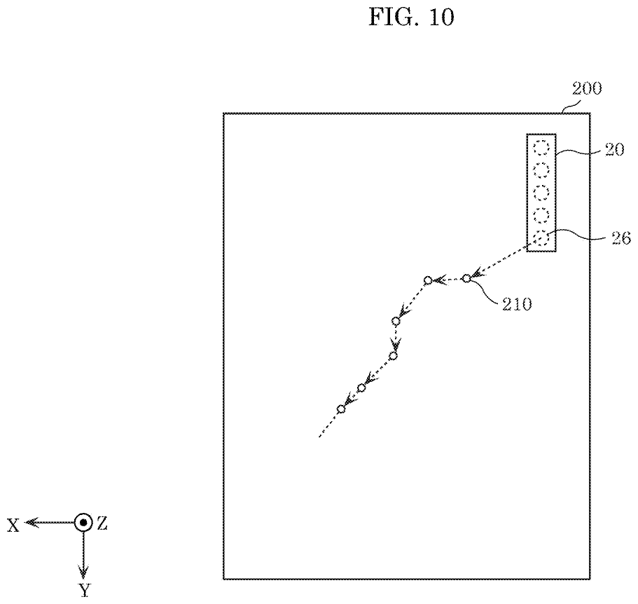

Next, the second movement method will be described with reference to FIG. 10.

FIG. 10 is a diagram for explaining an example of the second movement method. FIG. 10 is a top view (viewed from the plus side in the Z-axis direction) of board 200 and shows the movement route of supply head 20.

As shown in FIG. 10, the second movement method is a method in which supply head 20 moves one by one to each of the plurality of supply positions 210 in order based on the positional relationship of each of the plurality of supply positions 210. Specifically, a route for supplying the liquid agent is determined based on the positional relationship of each of the plurality of supply positions 210 so that the supply time of the liquid agent to each supply positions 210 is, for example, the shortest. In addition, as nozzle 26 used for supplying the liquid agent, nozzle 26 having the closest distance to supply positions 210 to which the liquid agent is supplied next is selected with respect to the current position of supply head 20. It should be noted that when the filling of the liquid agent in liquid agent storage 25 of that nozzle 26 is not completed, for example, the next closest nozzle 26 may be selected.

In addition, the timing at which the liquid agent is supplied does not need to be one after another for each of the plurality of supply positions 210, and when supply positions 210 are in a positional relationship in which the plurality of nozzles 26 can simultaneously supply the liquid agent, the liquid agent may be supplied at the same time.

The second movement method is a method that is advantageous in terms of supply time, for example, when the number of a plurality of supply positions 210 is small. When the number of the plurality of supply positions 210 is small and supply head 20 moves according to the first movement method, supply head 20 may move in a region where supply positions 210 does not exist at a high rate. That is, when the number of the plurality of supply positions 210 is small, supply head 20 may move wastefully in the first movement method. On the other hand, in the second movement method, since supply head 20 moves directly toward each of the plurality of supply positions 210, when the number of the plurality of supply positions 210 is small, wasteful movement is eliminated and is advantageous in terms of supply time.

As described above, calculator 113 calculates the supply time required for supplying the liquid agent to the plurality of supply positions 210 for each of the first movement method and the second movement method. Specifically, calculator 113 calculates the supply time for each of the first movement method and the second movement method according to the respective sizes of the plurality of supply positions 210 on board 200, the respective coordinates of the plurality of supply positions 210 on board 200, the size of board 200, and the like. In addition, selector 112 selects the movement method of supply head 20 from the plurality of movement methods based on the calculation result of the supply time. For example, when the number of the plurality of supply positions 210 is large, the supply time for the first movement method is shorter than the supply time for the second movement method, and selector 112 selects the first movement method. When the number of the plurality of supply positions 210 is small, the supply time for the second movement method is shorter than the supply time for the first movement method, and selector 112 selects the second movement method. It should be noted that depending on the tact time (line tact) and the like in mass production, it is not always necessary to select a movement method in which the supply time is short. In this way, the optimum supply time can be obtained by selecting the optimum movement method from the plurality of movement methods (specifically, the first movement method and the second movement method).

In addition, it is possible that a plurality of supply positions 210 are densely packed in a certain region of board 200, and a plurality of supply positions 210 are discrete in another region. In such a case, if supply head 20 can be moved according to only one of the first movement method or the second movement method, it takes time to supply the liquid agent at the location where the plurality of supply positions 210 are discrete with the first movement method, and it takes time to supply the liquid agent at the location where the plurality of supply positions 210 are densely packed with the second movement method.

Therefore, supply head mover 21 may move supply head 20 by combining the first movement method and the second movement method. In this case, as the supply time, for example, the time required to supply the liquid agent to supply positions 210 included in each region is calculated for each of the region where the plurality of supply positions 210 on board 200 are densely packed and the region where they are discrete. Then, based on the calculation result of the supply time, supply head 20 is moved in the region where the plurality of supply positions 210 are densely packed according to the first movement method, and supply head 20 is moved in the region where the plurality of supply positions 210 are discrete according to the second movement method. With this, the more optimum supply time can be obtained by combining the first movement method and the second movement method.

### Embodiment 2

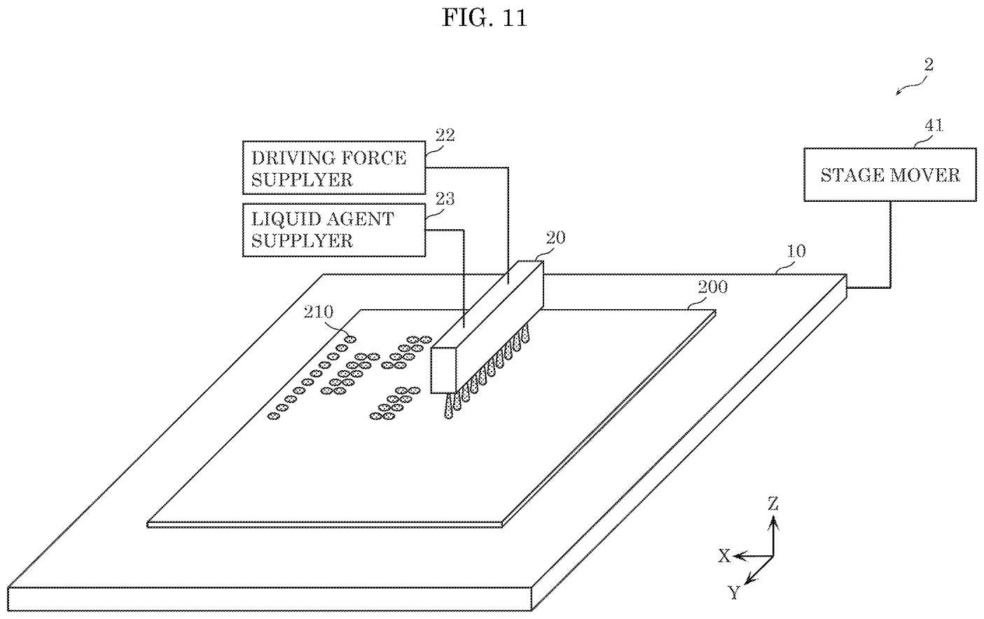

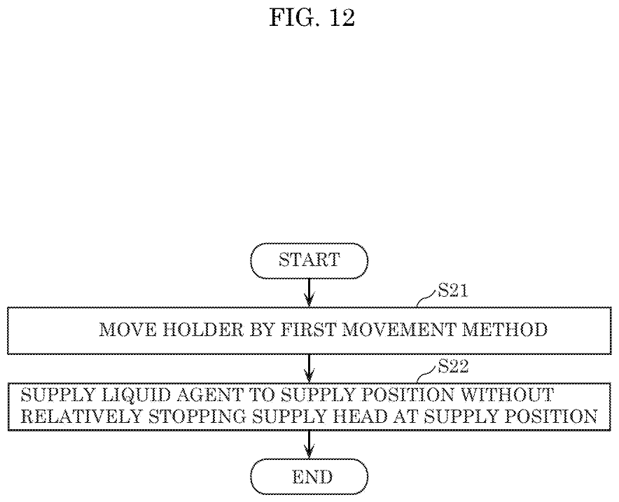

In Embodiment 1, the plurality of nozzles 26 supply the liquid agent to the plurality of supply positions 210 on board 200 by moving supply head 20, but supply head 20 itself does not have to move, and it is only necessary that supply head 20 moves relative to board 200. In liquid agent supply device 2 according to Embodiment 2, holder 10 includes a stage on which board 200 is placed (see FIG. 11), and supply head 20 moves relative to board 200 by the movement of holder 10 on which board 200 is placed. It should be noted that in the following description, it is assumed that holder 10 includes a stage, but holder 10 may include a clamping mechanism for clamping board 200, and supply head 20 may move relative to board 200 by the movement of holder 10 that clamps board 200. Since other points are the same as those in Embodiment 1, the description thereof will be omitted. Hereinafter, the points different from Embodiment 1 will be mainly described with reference to FIG. 11 and FIG. 12.

FIG. 11 is an external perspective view of the periphery of supply head 20 according to Embodiment 2.

As shown in FIG. 11, board 200 is placed on holder 10 (stage). Liquid agent supply device 2 includes stage mover 41 as a configuration for moving holder 10 on which board 200 is placed. It should be noted that in Embodiment 2, board 200 and supply head 20 move relatively by stage mover 41 moving holder 10 as the relative mover. In FIG. 11, the illustration of the specific configuration of stage mover 41 is omitted.

Holder 10 on which board 200 is placed can move in the X, Y, and Z-axis directions below supply head 20, and supply head 20 can supply the liquid agent to the plurality of supply positions 210 on board 200 during the movement. Supply head 20 moves in the X, Y, and Z axis directions relative to board 200 by the movement of holder 10 in the X, Y, and Z-axis directions.

Stage mover 41 causes holder 10 to move in the X, Y, and Z-axis directions. For example, stage mover 41 is configured by a linear motor or the like to which holder 10 is attached to enable holder 10 to move in the X, Y, and Z-axis directions. It should be noted that stage mover 41 may be configured by a ball screw or the like. Stage mover 41 relatively moves board 200 and supply head 20 according to the first movement method in which board 200 and supply head 20 relatively move along a predetermined direction determined regardless of supply positions 210 among the plurality of supply positions 210, in a supply range including the plurality of supply positions 210. Specifically, stage mover 41 moves holder 10 according to the first movement method. For example, in the present embodiment, the predetermined direction is determined in the X-axis direction regardless of supply positions 210. In addition, stage mover 41 relatively moves board 200 and supply head 20 according to the second movement method in which board 200 and supply head 20 move relative to each other based on the positional relationship of each of the plurality of supply positions 210. Specifically, stage mover 41 moves holder 10 according to the second movement method. When holder 10 moves according to the first movement method, the liquid agent is supplied to supply positions 210 without supply head 20 relatively stopping at supply positions 210. That is, when the plurality of nozzles 26 supply the liquid agent to supply positions 210, holder 10 does not stop.

Control regarding the movement of holder 10 is performed, for example, by computer 100 included in liquid agent supply device 2.

Controller 111 performs controls regarding the movement of holder 10. Specifically, controller 111 controls stage mover 41. Holder 10 is movable by controller 111 controlling stage mover 41. Specifically, holder 10 is movable by controller 111 controlling a linear motor or the like that generates a driving force for moving holder 10. In addition, supply head 20 can supply the liquid agent to board 200 by controller 111 controlling driving force supplier 22 and liquid agent supplier 23.

Selector 112 selects a relative movement method between board 200 and supply head 20 from a plurality of movement methods including the first movement method. Specifically, selector 112 selects one of the first movement method or the second movement method from the plurality of movement methods. A program that enables holder 10 to be moved according to a specific movement method, such as the first movement method and the second movement method, is stored in memory 120. Stage mover 41 moves holder 10 according to the selected movement method.

Calculator 113 calculates the supply time required for supplying the liquid agent to the plurality of supply positions 210 for each of the plurality of movement methods. It should be noted that the supply time may include not only the time for holder 10 to move (in other words, for supply head 20 to relatively move on board 200) to supply the liquid agent to the plurality of supply positions 210, but also the time for preparatory movements that need to be performed for supplying the liquid agent, and the like.

Next, as a relative movement method between board 200 and supply head 20, specifically, a movement method of holder 10 on which board 200 is placed will be described with reference to FIG. 8 to FIG. 10 and FIG. 12. First, the first movement method of holder 10 will be described.

FIG. 12 is a flowchart showing an example of the operation of liquid agent supply device 2 according to Embodiment 2.

First, controller 111 causes stage mover 41 to move holder 10 according to the first movement method in which holder 10 moves so that supply head 20 moves relative to board 200 along a specific direction determined regardless of supply positions 210 in supply range A including a plurality of supply positions 210 (Step S21). Here, the specific direction is the X-axis direction, which is a direction substantially orthogonal to the arrangement direction (Y-axis direction) of the plurality of nozzles 26. For example, in the first movement method, holder 10 moves so that supply head 20 moves on a straight line along a specific direction without changing the movement direction from the specific direction relative to board 200 within supply range A.

A plurality of nozzles 26 are arranged in supply head 20, and the liquid agent can be supplied to the plurality of supply positions 210 by the plurality of nozzles 26 while supply head 20 moves in a specific direction relative to board 200 by holder 10 moving according to the first movement method. For example, in FIG. 8, by one movement of holder 10 to the minus side in a specific direction (X-axis direction), supply head 20 including the plurality of nozzles 26 are arranged moves on route R1 relative to board 200 to the plus side in the specific direction (X-axis direction), and the liquid agent can be supplied to many supply positions 210 (here, six supply positions 210) at once, so that the time required for the supply (supply time) of the liquid agent to the plurality of supply positions 210 can be shortened. In FIG. 8, five nozzles 26 are shown as the plurality of nozzles 26, but in fact, thousands of nozzles 26 are arranged in supply head 20. Therefore, the liquid agent can actually be supplied to several thousands of supply positions 210 by one movement of holder 10 in a specific direction. In addition, since the time can be shortened by supplying the liquid agent to many supply positions 210 at once, it is not always necessary to move holder 10 at high speed in order to shorten the time.

For example, when holder 10 moves according to the first movement method, controller 111 causes the plurality of nozzles 26 to supply the liquid agent to supply positions 210 without stopping supply head 20 relatively at supply positions 210 (Step S22). As described above, since it is not always necessary to move holder 10 at high speed in order to shorten the time, by moving holder 10 at low speed, the liquid agent can be supplied without supply head 20 stopping relatively at supply positions 210, that is, without rapidly accelerating or decelerating holder 10. Therefore, it is not necessary to prepare a powerful drive source for realizing rapid acceleration/deceleration and a highly rigid housing that converges the vibration caused by rapid acceleration/deceleration, and the cost and size of the device can be reduced. It should be noted that in the first movement method, holder 10 may be moved so that supply head 20 moves at a constant speed in a specific direction in supply range A. With this, not only the rapid acceleration/deceleration of holder 10 but also the simple acceleration/deceleration can be suppressed, and the cost and size of the device can be further reduced.

In addition, in the first movement method, board 200 and supply head 20 relatively reciprocate along a specific direction. Specifically, in the first movement method, holder 10 reciprocates along a specific direction. With this, as shown in FIG. 8 and FIG. 9, in the first movement method, supply head 20 reciprocates relative to board 200 along a specific direction. With this, the liquid agent can be flexibly supplied to the plurality of supply positions 210 on board 200.

In addition, the route in which board 200 and supply head 20 relatively reciprocate includes an outward route and a return route with an interval therebetween. Specifically, the route in which holder 10 reciprocates includes an outward route and a return route with an interval therebetween. For example, by holder 10 reciprocating with interval L, supply head 20 reciprocates relative to board 200 as routes R1 and R2 with interval L therebetween, as shown in FIG. 8 and FIG. 9.

Interval L is determined so that, for example, the movement range on route R1 and the movement range on route R2 of supply head 20 do not overlap in the plan view of board 200, that is, when board 200 is viewed from the plus side in the Z-axis direction. Interval L shown in FIG. 8 is determined such that the movement range on route R1 and the movement range on route R2 of supply head 20 (specifically, the plurality of nozzles 26 groups) do not overlap in the plan view of board 200. With this, holder 10 moves, for example, from the plus side to the minus side in the Y-axis direction while reciprocating along a specific direction with certain interval L between the outward route and the return route so that supply head 20 moves from one end to the other end (for example, from the minus side to the plus side in the Y-axis direction) of board 200. Therefore, for example, even when the length from the one end to the other end of board 200 is larger than the length of supply head 20 including the plurality of nozzles 26 are arranged as shown in FIG. 8, and the liquid agent cannot be supplied to all of the plurality of supply positions 210 on board 200 by one movement in a specific direction of holder 10, the liquid agent can be supplied to all of the plurality of supply positions 210 by the reciprocating movement of holder 10.

In addition, interval L may be narrower than the interval in which the plurality of nozzles 26 are arranged. For example, as in supply positions 210a and 210b shown in FIG. 9, the interval between supply positions 210 may be narrower than the interval in which the plurality of nozzles 26 are arranged. This is because in recent years, the use of parts having a size that is difficult to see with the naked eye, such as the so-called 0201 size, has been increasing, and the interval between supply positions 210 has become narrower corresponding to the mounting land of such parts. In such a case, if interval L is determined so that the movement range on route R1 and the movement range on route R2 of supply head 20 relative to board 200 do not overlap in the plan view of board 200 as shown in FIG. 8, for example, the liquid agent may not be supplied to supply positions 210b. Therefore, interval L is made narrower than the interval in which the plurality of nozzles 26 are arranged as shown in FIG. 9. In other words, interval L is determined so that the movement range on route R1 and the movement range on route R2 of supply head 20 relative to board 200 overlap in the plan view of board 200. With this, supply head 20 gradually moves from one end to the other end of board 200, and the liquid agent can be accurately supplied to supply positions 210. For example, interval L is determined to about ¼ of the interval in which the plurality of nozzles 26 are arranged.

In addition, although not shown, the route in which board 200 and supply head 20 reciprocate relatively (specifically, the route in which holder 10 reciprocates) may include an outward route and a return route that are the same as each other. That is, when holder 10 reciprocates, the route that has moved may be returned and the same route may be moved again. The larger the mounting land size of the component, the larger the amount of liquid agent required, so that it may not be possible to supply a sufficient amount of the liquid agent to supply positions 210 corresponding to the mounting land by one movement of holder 10 in a specific direction depending on the size of the mounting land. In this case, the height of the liquid agent is not sufficient at supply positions 210, and there is a possibility that defects may occur in mounting parts or the like. On the other hand, the reciprocating movement of holder 10 is performed in the same route, and the liquid agent is supplied to the same supply positions 210 in each of the outward route and the return route, so that a sufficient amount of the liquid agent can be supplied to supply positions 210.

It should be noted that the size of interval L when reciprocating, whether or not the reciprocating movement is performed on the same route, and the like are determined based on the data (specifically, Gerber data and the like) regarding board 200 stored in memory 120. That is, there may be such a case that the movement method of holder 10 is different depending on a location of one board 200 relative to supply head 20 such as a location where interval L becomes large or small, or a location where holder 10 reciprocates on the same route.

Next, the second movement method of holder 10 will be described.

As shown in FIG. 10, the second movement method is a method in which holder 10 is moved so that supply head 20 moves one by one to each of the plurality of supply positions 210 in order based on the positional relationship of each of the plurality of supply positions 210. Specifically, a route for supplying the liquid agent is determined based on the positional relationship of each of the plurality of supply positions 210 so that the supply time of the liquid agent to each supply positions 210 is, for example, the shortest. In addition, as nozzle 26 used for supplying the liquid agent, nozzle 26 having the closest distance to supply positions 210 to which the liquid agent is supplied next is selected with respect to the current position of supply head 20. It should be noted that when the filling of the liquid agent in liquid agent storage 25 of that nozzle 26 is not completed, for example, the next closest nozzle 26 may be selected.

The second movement method is a method that is advantageous in terms of supply time, for example, when the number of a plurality of supply positions 210 is small. When the number of the plurality of supply positions 210 is small and supply head 20 moves according to the first movement method, supply head 20 may relatively move in a region where supply positions 210 does not exist at a high rate. That is, when the number of the plurality of supply positions 210 is small, holder 10 may move wastefully in the first movement method. On the other hand, in the second movement method, since holder 10 moves so that supply head 20 moves directly toward each of the plurality of supply positions 210, when the number of the plurality of supply positions 210 is small, wasteful movement is eliminated and is advantageous in terms of supply time.

As described above, calculator 113 calculates the supply time required for supplying the liquid agent to the plurality of supply positions 210 for each of the first movement method and the second movement method. Specifically, calculator 113 calculates the supply time for each of the first movement method and the second movement method according to the respective sizes of the plurality of supply positions 210 on board 200, the respective coordinates of the plurality of supply positions 210 on board 200, the size of board 200, and the like. In addition, selector 112 selects the movement method of supply head 20 from the plurality of movement methods based on the calculation result of the supply time. For example, when the number of the plurality of supply positions 210 is large, the supply time for the first movement method is shorter than the supply time for the second movement method, and selector 112 selects the first movement method. When the number of the plurality of supply positions 210 is small, the supply time for the second movement method is shorter than the supply time for the first movement method, and selector 112 selects the second movement method. It should be noted that depending on the tact time (line tact) and the like in mass production, it is not always necessary to select a movement method in which the supply time is short. In this way, the optimum supply time can be obtained by selecting the optimum movement method from the plurality of movement methods (specifically, the first movement method and the second movement method).

In addition, it is possible that a plurality of supply positions 210 are densely packed in a certain region of board 200, and a plurality of supply positions 210 are discrete in another region. In such a case, if holder 10 can be moved according to only one of the first movement method or the second movement method, it takes time to supply the liquid agent at the location where the plurality of supply positions 210 are discrete with the first movement method, and it takes time to supply the liquid agent at the location where the plurality of supply positions 210 are densely packed with the second movement method.

Therefore, stage mover 41 may move holder 10 by combining the first movement method and the second movement method. In this case, as the supply time, for example, the time required to supply the liquid agent to supply positions 210 included in each region is calculated for each of the region where the plurality of supply positions 210 on board 200 are densely packed and the region where they are discrete. Then, based on the calculation result of the supply time, holder 10 is moved according to the first movement method when supply head 20 is above the region where the plurality of supply positions 210 are densely packed, and holder 10 is moved according to the second movement method when supply head 20 is above the region where the plurality of supply positions 210 are discrete. With this, the more optimum supply time can be obtained by combining the first movement method and the second movement method.

### Other Embodiments

Liquid agent supply devices 1 and 2 of the present disclosure have been described above based on the embodiments, but the present disclosure is not limited to the above embodiments. Forms realized through various modifications to the present embodiments conceived by a person of ordinary skill in the art or through a combination of the components in different embodiments, so long as they do not depart from the essence of the present invention, may also be included in the scope of the present disclosure.

For example, in the above embodiment, when supply head 20 or holder 10 moves according to the first movement method, supply head 20 does not stop (does not relatively stop) at supply positions 210 to supply the liquid agent to supply positions 210, but it may stop.

In addition, for example, in the above embodiment, in the first movement method, supply head 20 or holder 10 reciprocates along a specific direction, but the reciprocating movement does not have to be performed and only one movement in a specific direction may be performed.

In addition, for example, in the above embodiment, the movement method of supply head 20 or holder 10 is selected from the plurality of movement methods, but the present disclosure is not limited thereto. For example, the movement method of supply head 20 or holder 10 may be only the first movement method.

In addition, for example, in the above embodiment, liquid agent supply devices 1 and 2 include recognizer 30, but they may not include it.

In addition, for example, in the above embodiment, holder 10 has a clamp mechanism, but it may not have it.

In addition, for example, the present disclosure can be realized not only as liquid agent supply devices 1 and 2, but also as a liquid agent supply method including steps (treatments) performed by each component configuring liquid agent supply devices 1 and 2.

Specifically, the liquid agent supply method is a liquid agent supply method for liquid agent supply devices 1 or 2 including; holder 10 that holds board 200; supply head 20 including a plurality of nozzles 26 for supplying a liquid agent to a plurality of supply positions 210 on board 200 held by holder 10 are arranged; and a relative mover (supply head mover 21 or stage mover 41) that relatively moves board 200 and supply head 20. In the liquid agent supply method, as shown in FIG. 7 or 12, the relative mover relatively moves board 200 and supply head 20 according to the first movement method in which board 200 and supply head 20 relatively move along a specific direction determined regardless of supply positions 210 among a plurality of supply positions 210, in supply range A including the plurality of supply positions 210 (Step S11 or Step S21).

In addition, for example, those steps may be performed by a computer (computer system). Then, the present disclosure can be realized as a program for causing a computer to execute the steps included in those methods. Furthermore, the present disclosure can be realized as a non-temporary computer-readable recording medium such as a CD-ROM on which the program is recorded.

For example, when the present disclosure is realized by a program (software), each step is executed by executing the program using hardware resources such as a CPU, memory, and input/output circuit of a computer. That is, each step is executed by the CPU acquiring data from the memory, the input/output circuit or the like to perform an operation, or outputting the operation result to the memory, the input/output circuit or the like.

In addition, the plurality of components included in liquid agent supply devices 1 and 2 of the above-described embodiments may be realized as dedicated or general-purpose circuits, respectively. These components may be realized as one circuit or as a plurality of circuits.

In addition, the plurality of components included in liquid agent supply devices 1 and 2 of the above-described embodiments may be realized as an LSI (Large Scale Integration) which is an integrated circuit (IC). These components may be individually integrated into one chip, or may be integrated into one chip so as to include a part or all of them. The LSI may be referred to as a system LSI, a super LSI, or an ultra LSI depending on the degree of integration.

In addition, the integrated circuit is not limited to the LSI, and may be realized by a dedicated circuit or a general-purpose processor. A programmable FPGA (Field Programmable Gate Array) or a reconfigurable processor in which the connection and settings of circuit cells inside the LSI can be reconfigured may be used.

Furthermore, when circuit integration technology that replaces LSIs comes along owing to advances of the semiconductor technology or to a separate derivative technology, the circuit integration of each component included in liquid agent supply devices 1 and 2 may understandably be performed using that technology.

In addition, a form obtained by applying various variations that a person skilled in the art can conceive to the embodiments, or a form realized by arbitrarily combining the components and functions in each embodiment within the scope without departing from the spirit of the present disclosure is also included in this disclosure.

### INDUSTRIAL APPLICABILITY

The present disclosure can be used, for example, in an apparatus or the like for supplying solder or the like to a mounting board.

### REFERENCE MARKS IN THE DRAWINGS

1, 2 Liquid agent supply device

10 Holder

11 Transporter

12 Loader

13 Unloader

20 Supply head

21 Supply head mover (relative mover)

22 Driving force supplier

23 Liquid agent supplier

24 Drive source

25 Liquid agent storage

26 Nozzle

30 Recognizer

41 Stage mover (relative mover)

100 Computer

110 Processor

111 Controller

112 Selector

113 Calculator

120 Memory

200 Board

210, 210a, 210b Supplier

A Supply range

L Interval

M Mark

R1, R2 Route

What is claimed is:

1. A liquid agent supply device, comprising:
a holder that holds a board;
a supply head including a plurality of nozzles for supplying a liquid agent to a plurality of supply positions on the board held by the holder are arranged; and
a relative mover that relatively moves the board and the supply head, wherein
the relative mover relatively moves the board and the supply head according to a first movement method in which the board and the supply head relatively move along a specific direction determined regardless of supply positions among the plurality of supply positions, in a supply range including the plurality of supply positions.

2. The liquid agent supply device according to claim 1, wherein
when the plurality of nozzles move according to the first movement method, the supply head supplies the liquid agent to the supply positions without relatively stopping at the supply positions.

3. The liquid agent supply device according to claim 1, wherein
the board and the supply head reciprocate relatively along the specific direction in the first movement method.

4. The liquid agent supply device according to claim 3, wherein
a route in which the board and the supply head reciprocate relatively includes an outward route and a return route with an interval therebetween.

5. The liquid agent supply device according to claim 4, wherein
the interval is narrower than an interval at which the plurality of nozzles are arranged.

6. The liquid agent supply device according to claim 3, wherein
a route in which the board and the supply head reciprocate relatively includes an outward route and a return route that are a same route.

7. The liquid agent supply device according to claim 1, further comprising:
a selector that selects a relative movement method between the board and the supply head from a plurality of movement methods including the first movement method; and
a calculator that calculates, for each of the plurality of movement methods, a supply time required for supplying the liquid agent to the plurality of supply positions, wherein
the selector selects a relative movement method between the board and the supply head from the plurality of movement methods based on a calculation result of the supply time.

8. The liquid agent supply device according to claim 7, wherein
the relative mover relatively moves the board and the supply head according to a second movement method in which the board and the supply head move relative to each other based on a positional relationship between the plurality of supply positions, and
the selector selects one of the first movement method and the second movement method from the plurality of movement methods.

9. The liquid agent supply device according to claim 8, wherein
the relative mover relatively moves the board and the supply head by combining the first movement method and the second movement method.

10. The liquid agent supply device according to claim 1, further comprising:
a recognizer that recognizes a mark attached to the board.

11. The liquid agent supply device according to claim 1, wherein
the holder has a clamping mechanism for clamping the board.

12. The liquid agent supply device according to claim 1, wherein
the liquid agent is solder.

13. A method for supplying a liquid agent for a liquid agent supply device that includes:
a holder that holds a board;
a supply head including a plurality of nozzles for supplying the liquid agent to a plurality of supply positions on the board held by the holder are arranged; and
a relative mover that relatively moves the board and the supply head, the method comprising:
relatively moving the board and the supply head according to a first movement method in which the board and the supply head relatively move along a specific direction determined regardless of supply positions among the plurality of supply positions, in a supply range including the plurality of supply positions.
